(19) United States
(12) Patent Application Publication
(10) Pub. No.: US 2015/0034589 A1
(43) Pub. Date: Feb. 5, 2015

(54) SYSTEM AND METHOD FOR FORMING PATTERNED COPPER LINES THROUGH ELECTROLESS COPPER PLATING

(71) Applicant: Lam Research Corporation, Fremont, CA (US)

(72) Inventors: Alan Lee, San Jose, CA (US); Yunsang Kim, Monte Sereno, CA (US); Andrew Bailey, III, Pleasanton, CA (US); Yezdi Dordi, Palo Alto, CA (US); William Thie, Mountain View, CA (US)

(21) Appl. No.: 14/517,675

(22) Filed: Oct. 17, 2014

Related U.S. Application Data
(62) Division of application No. 11/461,415, filed on Jul. 31, 2006, now abandoned.
(60) Provisional application No. 60/713,494, filed on Aug. 31, 2005.

(51) Int. Cl. H05K 3/18; H05K 3/06

(52) U.S. Cl. CPC H05K 3/184; H05K 3/064; H05K 2203/0571; H05K 2203/072; H05K 2203/087
USPC 216/17

(57) ABSTRACT

A method for forming copper on a substrate including inputting a copper source solution into a mixer, inputting a reducing solution into the mixer, mixing copper source solution and the reducing solution to form a plating solution having a pH of greater than about 6.5 and applying the plating solution to a substrate, the substrate including a catalytic layer wherein applying the plating solution to the substrate includes forming a catalytic layer, maintaining the catalytic layer in a controlled environment and forming copper on the catalytic layer. A system for forming copper structures is also disclosed.

### CROSS REFERENCE TO RELATED APPLICATIONS

This application is a divisional of and claims priority from U.S. patent application Ser. No. 11/461,415, which was filed on Jul. 31, 2006 and entitled “System and Method for Forming Patterned Copper Lines Through Electroless Copper Plating,” which is incorporated herein by reference in its entirety. Through U.S. patent application Ser. No. 11/461,415, this application also claims priority from U.S. Provisional Patent Application No. 60/713,494 filed on Aug. 31, 2005 and entitled “High Rate Electroless Plating and Integration Flow to Form Cu Interconnects,” which is incorporated herein by reference in its entirety.

### BACKGROUND

The present invention relates generally to Semiconductor manufacturing processes, and more particularly, to systems and methods for forming patterned copper lines through electroless copper plating.

Formation of copper lines for use in an interconnect process is typically done by a dual damascene process, in which trenches are formed in a dielectric material, barrier metal and copper are deposited such that the trenches are filled, and an overburden is formed. The overburden in the field regions adjacent to the trenches is typically removed using a chemical-mechanical planarization process. Trenches on different levels are connected by copper-filled via holes, as known and understood by those skilled in the art.

The integration of a dual damascene technology becomes more difficult as the inter-metal dielectric migrates to increasingly lower dielectric constant values, becoming more brittle, porous and less compatible with the standard process techniques used to etch, clean and planarize the materials. Further, increasing porosity of the low-K materials is limited by the integration issues encountered. It is desirable to eliminate the dielectric material altogether and use an air gap as a dielectric between copper lines, but until now there has not been a viable integration scheme that can achieve an air gap dielectric.

Typically, electroless copper plating uses a solution of copper ions in an alkaline solution with a reducing agent. A substrate, such as a semiconductor wafer, is placed within the alkaline solution. In the presence of a catalytic surface on the substrate, the copper ions are reduced by the reducing agent to form a layer or film of copper on the surface of the substrate.

An aldehyde (e.g., formaldehyde) solution is a common reducing agent used in the electroless plating solutions. The formaldehyde substantially reduces the copper ion to elemental copper. Unfortunately this reduction process produces hydrogen that can be incorporated into the matrix of the copper, causing voids and reducing the quality of the deposited copper layer.

Another limitation of the typical alkaline solution electroless copper plating process includes a relatively slow growth rate of the resulting copper oxide layer. By way of example, the typical alkaline solution electroless copper plating has a maximum growth rate of about 100-500 angstroms per minute. This limited growth rate requires excessive amounts of time to grow thick films (e.g., greater than about 100 micron thickness). As the growth rate is so limited, the typical alkaline solution electroless copper plating process requires batch wafer processing to achieve significant wafer volume throughput. However, batch wafer processing can be difficult to accurately and repeatably produce the desired process results throughout each batch of wafers.

Yet another limitation of the typical alkaline solution electroless copper plating process is the alkaline nature of the alkaline solution. It is desirable to form specific copper structures (e.g., patterned copper lines) and not a uniform blanket of copper (e.g., when considering air-gap dielectric or other processes). A lithographic process applied to a photoresist layer could form pre-patterned features. The typical alkaline solution electroless copper plating process requires that the structures be formed in a typical photoresist patterning process. Unfortunately, the photoresist is highly reactive with and would be substantially damaged or even entirely destroyed by the alkaline nature of the alkaline solution. As a result, a protective layer that is not reactive with the alkaline solution must first be formed over the photoresist pattern. The protective layer protects the photoresist pattern from damage by the typical alkaline solution during the electroless copper plating process.

Alternatively, the photoresist may be used to transfer a pattern into an underlying layer of material that is compatible with the alkaline electroless chemistry. The photoresist is then removed and the copper lines could be formed in a positive image of the desired copper structures. In this instance, the patterning layer is either a low K material which becomes an integral part of the interconnect layer, or can be removed as a sacrificial material. In either case, removal of this material is more difficult than removal of the previously formed photoresist pattern.

In view of the foregoing, there is a need for a simplified system and method for forming patterned copper lines through electroless copper plating that also achieves a growth greater than 500 angstroms per minute and allow an air gap dielectric isolation between the copper lines.

### SUMMARY

Broadly speaking, the present invention fills these needs by providing a system and method for forming patterned copper lines through electro-less copper plating. It should be appreciated that the present invention can be implemented in numerous ways, including as a process, an apparatus, a system, computer readable media, or a device. Several inventive embodiments of the present invention are described below.

One embodiment provides a method for forming copper on a substrate including inputting a copper source solution into a mixer, inputting a reducing solution into the mixer, mixing copper source solution and the reducing solution to form a plating solution having a pH of greater than about 6.5 and applying the plating solution to a substrate, the substrate including a catalytic layer wherein applying the plating solution to the substrate includes forming copper on the catalytic layer.

The plating solution can be created substantially simultaneously with applying the plating solution to the substrate. The plating solution can have a pH of between about 7.2 and about 7.8. The plating solution can be discarded after forming copper on the catalytic layer.

The substrate can include a patterned photoresist layer and wherein the patterned photoresist layer exposes a first portion of the catalytic layer and wherein applying the plating solution to the substrate can include forming copper on the first portion of the catalytic layer. The method can also include removing the plating solution from the substrate, rinsing the substrate and drying the substrate.

The method can also include removing the patterned photoresist. Removing the patterned photoresist exposes a second portion of the catalytic layer. The second portion of the catalytic layer can also be removed.

The plating solution is compatible with an unprotected photoresist. The copper formed on the catalytic layer can be substantially elemental copper. The copper formed on the catalytic layer can be substantially free of hydrogen inclusions.

The copper formed on the catalytic layer is formed at a rate of greater than about 500 angstrom per minute. The plating solution can be applied to the substrate through a dynamic liquid meniscus and wherein the dynamic liquid meniscus is formed between a proximity head and a surface of the substrate. The copper source solution can include an oxidizing copper source, a complexing agent, a pH adjuster agent and a halide ion. The reducing solution can include a reducing ion.

The catalytic layer can include more than one layer. The catalytic layer can include a bottom anti-reflection coating (BARC) layer.

Another embodiment provides a method for forming a patterned copper structure on a substrate. The method includes receiving a substrate that includes a catalytic layer formed thereon and a patterned photoresist layer formed on the catalytic layer. The patterned photoresist layer exposes a first portion of the catalytic layer and the patterned photoresist layer covers a second portion of the catalytic layer. A copper source solution is input into a mixer and a reducing solution is input into the mixer. The copper source solution and the reducing solution are mixed to form a plating solution having a pH of between about 7.2 and about 7.8. The plating solution is applied to a substrate including forming copper on the first portion of the catalytic layer.

Yet another embodiment provides a process tool including a low pressure process chamber, an atmospheric pressure process chamber, a transfer chamber coupled to each of the low pressure process chamber and the atmospheric pressure process chamber, the transfer chamber including a controlled environment. The transfer chamber providing a controlled environment for transferring a substrate from the low pressure process chamber to the atmospheric pressure process chamber. A controller is also coupled to the low pressure process chamber, the atmospheric pressure process chamber and the transfer chamber. The controller including logic to control each of the low pressure process chamber, the atmospheric pressure process chamber and the transfer chamber.

The low pressure process chamber can include more than one low pressure process chambers that can include a plasma etch/removal chamber and the atmospheric pressure processing chamber can include a copper plating chamber. The copper plating chamber can include a mixer. The plasma chamber can be a downstream plasma chamber. At least one of the etch/removal chambers can be a wet process chamber.

The transfer chamber includes an input/output module. The control system can include a recipe including logic for loading a patterned substrate into the copper plating chamber, logic for inputting a copper source solution into the mixer, logic for inputting a reducing solution into the mixer, logic for mixing the copper source solution and the reducing solution to form a plating solution having a pH of greater than about 6.5; and logic for applying the plating solution to a patterned substrate, the patterned substrate including a catalytic layer wherein applying the plating solution to the substrate includes forming copper on the catalytic layer.

The patterned substrate can include a patterned photoresist layer formed on the catalytic layer wherein the patterned photoresist layer exposes a first portion of the catalytic layer and wherein the patterned photoresist layer covers a second portion of the catalytic layer. The plasma chamber can be a downstream plasma chamber.

Other aspects and advantages of the invention will become apparent from the following detailed description, taken in conjunction with the accompanying drawings, illustrating by way of example the principles of the invention.

### BRIEF DESCRIPTION OF THE DRAWINGS

The present invention will be readily understood by the following detailed description in conjunction with the accompanying drawings.

FIG. 1 is a flowchart diagram that illustrates the method operations performed in forming copper structures in a non-alkaline electroless copper plating, in accordance with one embodiment of the present invention.

FIGS. 2A through 2F illustrate copper structures formed on a substrate, in accordance with one embodiment of the present invention.

FIG. 3 is a flowchart diagram that illustrates the method operations performed in a high rate non-alkaline electroless copper plating process, in accordance with one embodiment of the present invention.

FIG. 4A is a simplified schematic diagram of a plating processing tool, in accordance with one embodiment of the present invention.

FIG. 4B illustrates a preferable embodiment of an exemplary substrate processing that may be conducted by a proximity head, in accordance with one embodiment of the present invention.

FIG. 5 is a simplified schematic diagram of a modular processing tool, in accordance with one embodiment of the present invention.

FIG. 6 is a simplified schematic diagram of an exemplary downstream plasma chamber, in accordance with one embodiment of the present invention.

### DETAILED DESCRIPTION

Several exemplary embodiments for systems and methods for forming patterned copper lines through electroless copper plating will now be described. It will be apparent to those skilled in the art that the present invention may be practiced without some or all of the specific details set forth herein.

The present invention provides a system and a method for an improved electroless copper plating process that is substantially not reactive to photoresist and that can allow a higher growth rate than about 500 angstroms per minute. Such a higher growth rate allows effective throughput for a single wafer process rather than the typical batch wafer process although it should be understood that the present invention can be used in a batch (e.g., multiple wafer) process.

The high rate, electroless plating process can include copper ions suspended in a substantially neutral or even an acidic solution. The neutral or acidic solution does not react with the photoresist. Therefore, photoresist patterning can be used to directly define the desired copper structures without the need of additional the process steps of adding a protective layer to the photoresist and/or forming a pattern with a material that is not reactive with to the prior art alkaline, electroless plating solution.

The high rate, electroless plating process can form a copper layer up to about 2500 angstroms per minute. The high rate, electroless plating process can therefore form a thicker copper layer much faster than the typical alkaline solution electroless copper plating process. As a result, the high rate, electroless plating process can be used to form thicker copper structures that the typical alkaline solution electroless copper plating process cannot.

The high rate, electroless plating process can include using cobalt ions (e.g., Co+, Co +2 and Co+3) instead of an aldehyde as the reducing agent. The cobalt ions substantially reduce the copper oxide to elemental copper with minimal production of hydrogen.

Since the high rate, electroless plating process can use the photoresist patterning to directly form the desired copper structures, several process steps required to form conventional in-laid copper lines using the dual damascene method described above are no longer required. Specifically, no protective layer is needed to protect the photoresist. Further, an etch process to remove the patterning material is also eliminated. This can also allow a modified integration path or process to decrease process operations and thereby reduce production time and increase throughput.

The copper structures formed by the high rate, electroless plating process can include wire-bond pads and ball grid arrays as may be used to form electrical connections to an integrated circuit in the packaging of the integrated circuit or in 3-D packaging interconnects. The free-standing copper structures may also enable formation and use of an air gap between metal lines to reduce the dielectric constant of the metal-to-metal space. By way of example, when forming an air-gap dielectric, the substrate could be pre-patterned with features that are ‘placeholders’ for the air gap or low K dielectric. The placeholders can be easily removable. The pre-patterned features can be formed by a lithographic process in photoresist, thereby avoiding an etch patterning step.

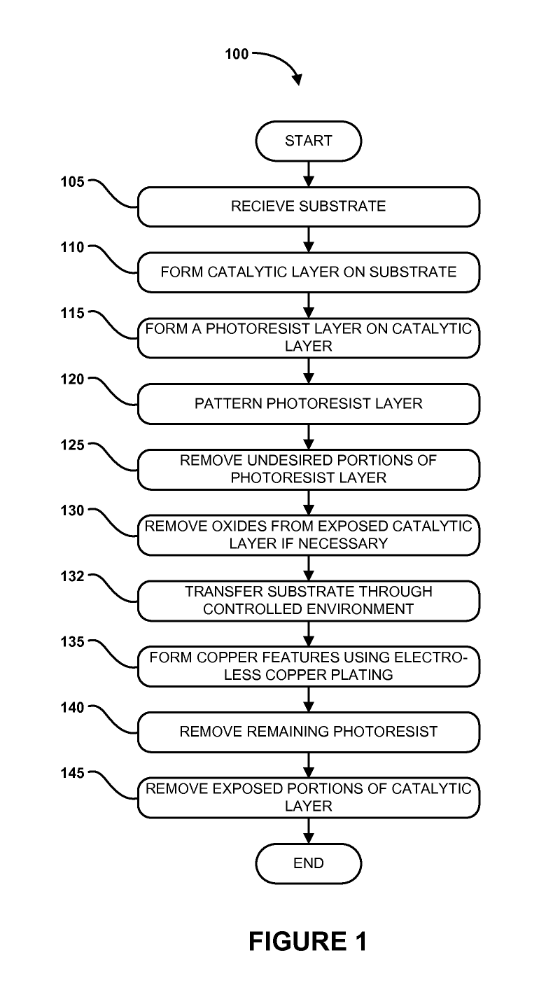

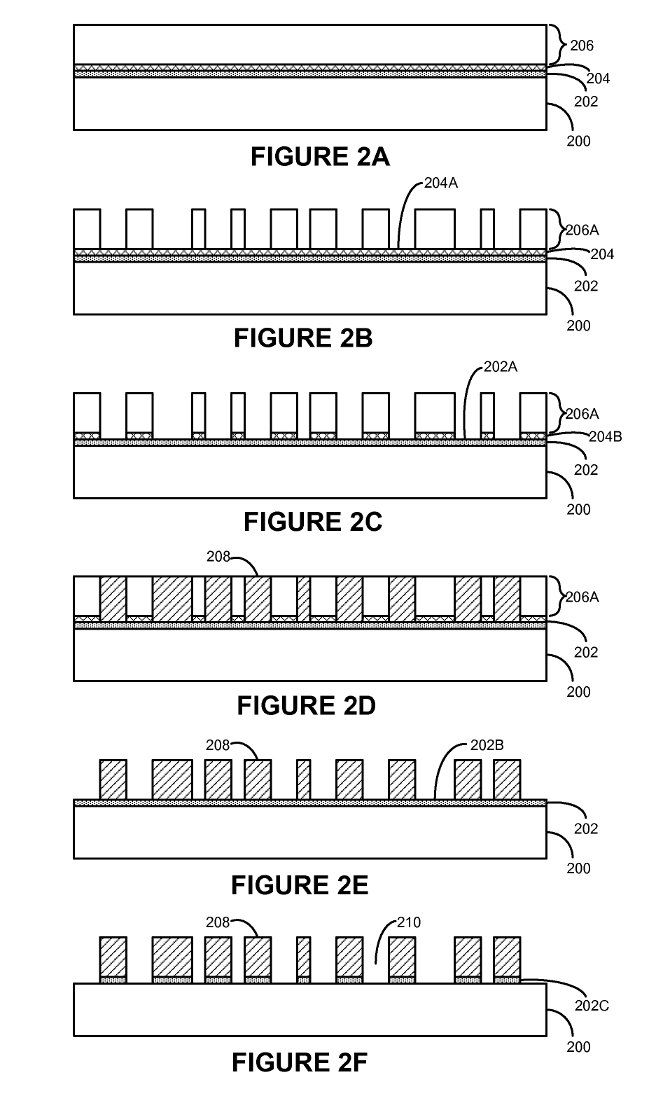

FIG. 1 is a flowchart diagram that illustrates the method operations 100 performed in forming copper structures in a non-alkaline electroless copper plating, in accordance with one embodiment of the present invention. FIGS. 2A through 2F illustrate copper structures 208 formed on a substrate (e.g., a wafer) 200, in accordance with one embodiment of the present invention. In an operation 105, the substrate 200 is received. The substrate 200 is previously prepared to be ready to form copper interconnect structures. This previous preparation can be performed by any suitable methods.

Referring now to FIGS. 1 and 2A, in an operation 110, a catalytic layer 202 is formed on the substrate 200. The catalytic layer 202 can be any suitable materials or combinations of materials and layers of materials. By way of example, the catalytic layer 202 can be formed from tantalum, ruthenium, nickel, nickel molybdenum, titanium, titanium nitride or other suitable catalytic materials. The catalytic layer 202 can be as thin as possible (e.g., a monolayer of the atoms or molecules) or a between a monolayer and up to about 500 angstroms thick. Combinations of layers can also be used. By way of example a tantalum layer can be formed on the substrate 200 and a ruthenium layer can be formed on the tantalum layer. The tantalum layer can be about 360 angstroms or even thinner. The ruthenium layer can be used to protect the tantalum layer from, for example, tantalum-oxide formation. The ruthenium layer can be about 150 angstroms or even thinner.

Forming the catalytic layer 202 can also include forming an optional antireflective coating (e.g., BARC) layer 204. The BARC layer 204 can be for example about 600 angstroms thick. The BARC layer 204 is well known in the art for providing improved lithography performance by reducing constructive and destructive interference during the exposure step.

In an operation 115, a photoresist layer 206 is formed on the catalytic layer 202. The photoresist layer 206 can be about 6000 angstroms thick or thicker or thinner. The photoresist layer 204 can be any suitable photoresist material as are well known in the art. In an operation 120, the photoresist layer 206 is patterned. Patterning the photoresist layer 206 also includes patterning the optional BARC layer 204 if the BARC layer is included.

Referring now to FIGS. 1 and 2B, in an operation 125, the undesired portions of the photoresist layer 206 are removed leaving only desired portions of the photoresist layer 206A. Exposed portions 204A of the optional BARC layer 204 are removed by a plasma etch process. By way of example, the BARC can be removed using a Lam Research Corporation 2300 Exelan® plasma etcher with a settings of about 20 degrees C., 40-100 mTorr, 200-700 W @ 27 MHz, 500-100 W @ 2 MHz, 100-500 sccm Argon, 0-100 sccm CF₄, 0-30 sccm oxygen, 0-150 sccm nitrogen, 0-150 sccm hydrogen and 0-10 sccm C₄F₈ for between about 20 and about 90 seconds. Various combinations and permutations of the gases and settings listed above may be used, depending on the material requirements. It should be understood that one skilled in the art could also remove the BARC using an inductively coupled plasma source (e.g., as available from Lam Research's Versys™ plasma process chamber).

Referring now to FIGS. 1 and 2C, in an operation 130, any oxides or other residues on the exposed portions 202A of the catalytic layer 202 are removed, if necessary. One approach to removing any oxides or other residues on the exposed portions 202A of the catalytic layer includes applying a plasma-generated radicals to the exposed portions 202A of the catalytic layer. By way of example, the oxides and other residues on the exposed portions 202A can be removed by applying radicals generated in a Lam 2300 Microwave Strip chamber, or similar chamber, with the following recipe: 700 sccm of a 3.9% concentration of hydrogen in helium carrier gas at 1 Torr, 1 kW for about 5 minutes. Ammonia (NH₃) or carbon monoxide (CO) can be used instead of or in combination with the 3.9% hydrogen. Alternatively, 100% hydrogen could be used at an elevated temperature. By way of example, between about 50 and about 300C, however the upper temperature limit is determined by the ability of the photoresist and BARC materials to withstand the elevated temperature conditions. A further variation can include a short controlled plasma oxidation process applied to remove any organic contaminants followed by the reduction operation described above to convert (i.e., reduce) the oxides that may be formed to their respective elemental metallic states. In an operation 132, the substrate is transferred in a controlled environment (i.e. in-situ to maintain low oxygen and low moisture levels) to the electroless plating process chamber. This ensures that the reduced surface formed in operation 130 is preserved as a catalytic layer.

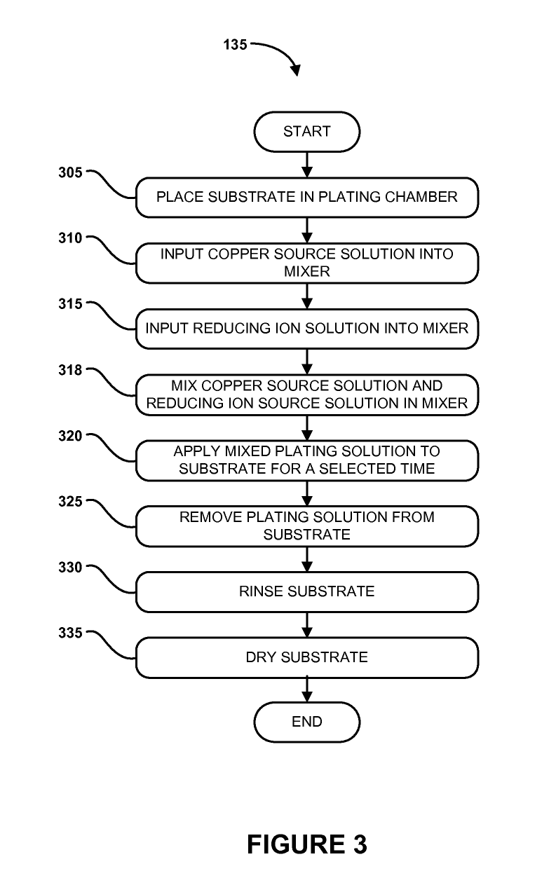

Referring now to FIGS. 1 and 2D, in an operation 135, a non-alkaline electroless copper plating process is applied to the substrate 200 to form copper structures 208. The non-alkaline electroless copper plating process is described in more detail in FIG. 3 below. The non-alkaline electroless copper plating process can generate between 500 to 2000 angstroms of elemental copper per minute. The non-alkaline electroless copper plating process can be applied to the substrate 200 in a vertical or horizontal immersion type of application. Alternatively, the non-alkaline electroless copper plating process can be applied to the substrate 200 through a dynamic liquid meniscus described in more detail below.

Referring now to FIGS. 1 and 2E, in an operation 140, the remaining portions 206A of the photoresist layer are removed to expose portions of the catalytic layer 202B. If the optional BARC layer 204 was included then the remaining portions 204B of the optional BARC layer are also removed when the remaining portions 206A of the photoresist layer are removed or subsequently thereafter. The photoresist and the BARC layer can be removed with a plasma process. Optionally, a wet chemical photoresist removal step can be performed using aqueous, semi-aqueous or non-aqueous solvents. An exemplary recipe for removing the remaining photoresist 206A and the remaining portions 204B of the optional BARC layer includes a temperature of less than about 30 degrees C., a pressure of about 5 mTorr, a flow rate of about 50 sccm of argon and 350 sccm of oxygen with about 1000-1400W source power at about 27 MHz is applied for about 3 min. Next, at a temperature of greater than about 30 degrees C., a pressure of about 5 mT, a flow rate of about 50 sccm argon and 350 sccm oxygen, with 1200W source power at about 27 MHz plus about 500W of bias power applied for about 30 seconds. The additional bias power causes the etching process to be more directional into the spaces 210 between the copper structures 208. By way of example, the BARC can be removed using a Lam Research Corporation 2300 Exelan® plasma etcher with a settings of about 20 degrees C., 40-100 mTorr, 200-700 W @ 27 MHz, 500-100 W @ 2 MHz, 100-500 sccm Argon, 0-100 sccm CF₄, 0-30 sccm oxygen, 0-150 sccm nitrogen, 0-150 sccm hydrogen and 0-10 sccm C₄F₈ for between about 20 and about 90 seconds. Various combinations and permutations of the gases and settings listed above may be used, depending on the material requirements. It should be understood that one skilled in the art could also remove the BARC using an inductively coupled plasma source (e.g., as available from Lam's Versys™ plasma process chamber).

Referring now to FIGS. 1 and 2F, in an operation 145, the exposed portions 202B of the catalytic layer 202 are removed. Removing the exposed portions 202B of the catalytic layer 202 substantially prevents the exposed portions of the catalytic layer from electrically connecting the remaining free standing copper structures 208. An exemplary recipe for removing the exposed portions 202B of the catalytic layer 202 using a Lam 2300 Versys plasma etcher includes a temperature of about 20 to about 50 degrees C. with about 500W source power and about 20-100 W bias power, with a pressure of about 50 mT and flow rates of about 30 sccm of CF₄ and 75 sccm of argon for a duration of about 1 minute. Other halogen-containing gases such as C₄F₈, or mixtures of halogen-containing gases such as CF₄+HBr, can be used in addition to or instead of the CF₄. The free standing copper structures 208 include the remaining portions 202C of the catalytic layer. Air gaps 210 are formed between the free standing copper structures 208. The air gaps 210 can allow an air dielectric to be used in subsequent structures formed on the free standing copper structures 208. The air gaps 210 can be between less than about 10 nm or larger in width. The free standing copper structures 208 can be any width desired. By way of example, the free standing copper structures 208 can be between less than about 10 nm and more than about 100 nm. The free standing copper structures 208 can be about 300 nm or larger in width. The maximum width of the free standing copper structures 208 is limited only by the width of the substrate.

The photoresist 206A removal in operation 140, above, can be performed with or without bias power depending on the requirements (e.g., to minimize damage to the copper structures 208 or to facilitate full removal of the photoresist between the copper structures 208). As a result, a short photoresist removal operation including applying 500 W bias, can be added to further remove the photoresist 206A and any residues thereof, between the copper structures 208. Applying the 500 W bias will also remove the ruthenium, if the ruthenium layer was also applied to protect the catalytic layer.

Each of the operations 105-145 involve low temperature of less than about 300 degrees C. to substantially limit migration of copper that may occur at higher temperatures. The BARC removal and pretreatment operation is also performed at a low temperature so as to limit the reticulation of photoresist at higher temperatures.

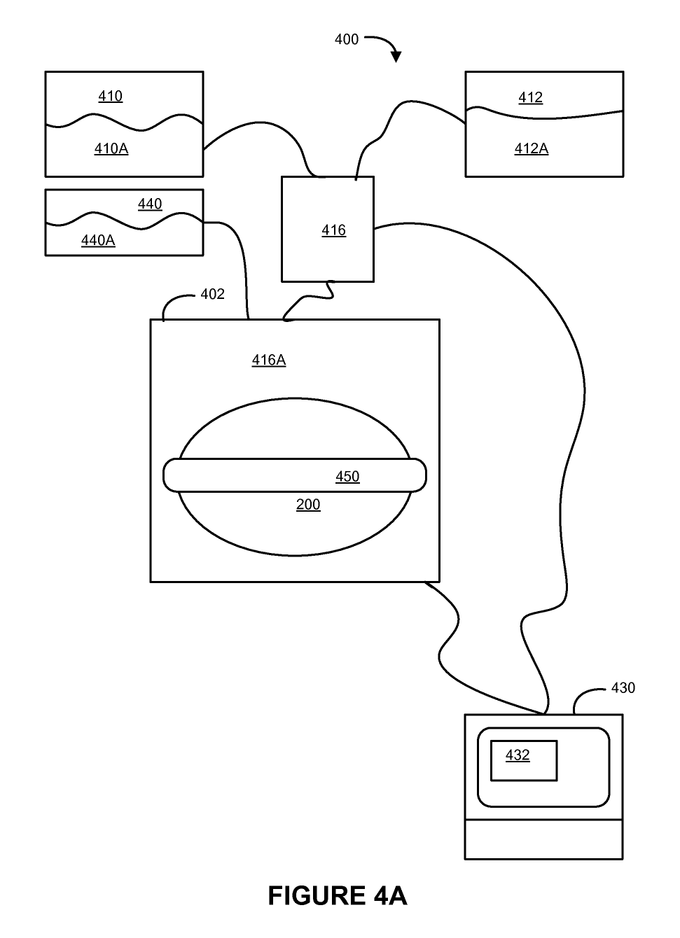

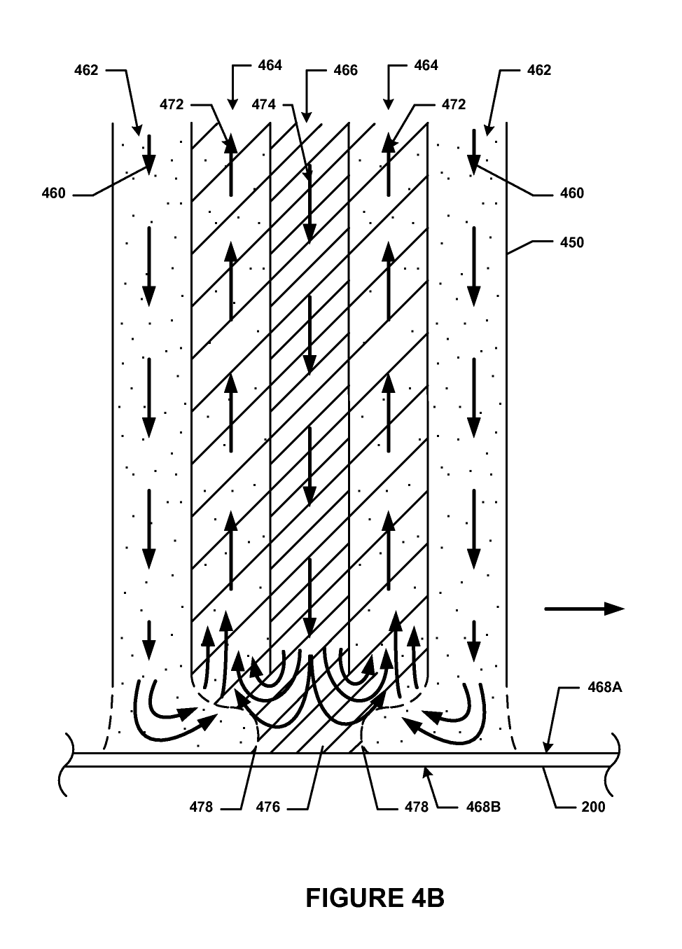

FIG. 3 is a flowchart diagram that illustrates the method operations 135 performed in a high rate non-alkaline electroless copper plating process, in accordance with one embodiment of the present invention. FIG. 4A is a simplified schematic diagram of a plating processing tool 400, in accordance with one embodiment of the present invention. The plating processing tool 400 includes a first source 410 and a second source 412. The first source 410 includes quantity of a first source material 410A. The second source 412 includes a quantity of a second source material 412A. The first source 410 and the second source 412 are coupled to a mixer 416. The mixer 416 is coupled to the plating chamber 402. The plating processing tool 400 can also include a rinsing solution source 440 that is coupled to the plating chamber 402. The rinsing solution source 440 can provide a quantity of rinsing solution 440A.

The plating processing tool 400 can also include a controller 430. The controller 430 is coupled to the plating chamber and the mixer 416. The controller 430 controls the operations (e.g., mixing, filling, rinsing, etc.) in the plating processing tool 400 according to a recipe 432 included in the controller.

Referring now to FIGS. 3 and 4A, in an operation 305, the substrate 200 is placed in the plating chamber 402 for the plating operation.

In operations 310 and 315, the mixer 416 mixes the first source material 410A and the second source material 412A to form the plating solution 416A. The first source material 410A is a reducing ion relative to the copper ion (e.g., Co²⁺). The second source material 412A includes a oxidizing copper source (e.g., Cu²⁺), a complexing agent (e.g., ethylene diamine, di-ethylene triamine), a pH adjuster agent (e.g., HNO₃, H₂SO₄, HCl, etc.) and a halide ion (e.g., Br—, Cl—, etc.). Additional details and examples regarding copper plating solutions are described in more detail in co-owned U.S. patent application Ser. No. 11/382,906 entitled Plating Solution for Electroless Deposition of Copper by Vaskelis et al., which was filed on May 11, 2006, and co-owned U.S. patent application Ser. No. 11/427,266 entitled Plating Solutions for Electroless Deposition of Copper by Dordi et al., which was filed on Jun. 28, 2006 and which are incorporated by reference herein, in their entirety for all purposes. This application is also related to co-owned U.S. patent application Ser. No. 11/398,254 entitled Methods and Apparatus for Fabricating Conductive Features on Glass Substrates used in Liquid Crystal Displays by Jeffrey Marks and which was filed on Apr. 4, 2006 and is incorporated by reference herein, in its entirety for all purposes.

In an operation 320, the plating solution 416A is output from the mixer 416 into the plating chamber 402 where the plating solution is applied to the substrate 200. The mixer 416 mixes the first source material 410A and the second source material 412A as needed in the plating chamber 402. The plating solution 416A has a pH of greater than about 6.5 and in at least one embodiment has a pH of within a range of about 7.2 to about 7.8. The plating solution 416A forms a layer of elemental copper substantially without any voids caused by hydrogen inclusions.

In an operation 325, the substrate 200 is removed from the plating solution 416A. Removing the substrate 200 from the plating solution 416A can include removing the substrate 200 from the plating chamber 402 and/or removing the plating solution 416A from the plating chamber 402.

In an operation 330, the substrate 200 is rinsed in a rinsing solution. By way of example, in operation 325, the plating solution 426A can be removed from the plating chamber 402 and the rinsing solution 440A can be input to the plating chamber to rinse substantially any remaining plating solution 416A off of the substrate 200.

In an operation 335, the substrate 200 can be dried. By way of example, the substrate 200 can be removed from the plating chamber 402 and placed in a second chamber (e.g., a spin, rinse and dry chamber) for rinsing and drying. Alternatively, the plating chamber 402 can include the mechanisms required to rinse and dry the substrate 200.

By way of example, the plating chamber 402 can include a proximity head 450 capable of rinsing and drying the substrate 200. The proximity head 450 can also apply the plating solution to the substrate. Various embodiments of the proximity head 450 are described in more detail in co-owned U.S. patent application Ser. No. 10/330,843 filed on Dec. 24, 2002 and entitled “Meniscus, Vacuum, IPA Vapor, Drying Manifold,” and co-owned U.S. patent application Ser. No. 10/261,839 filed on Sep. 30, 2002 and entitled “Method and Apparatus for Drying Semiconductor Wafer Surfaces Using a Plurality of Inlets and Outlets Held in Close Proximity to the Wafer Surfaces.” Various embodiments and applications of the proximity head 450 are also described in co-owned U.S. patent application Ser. No. 10/330,897, filed on Dec. 24, 2002, entitled “System for Substrate Processing with Meniscus, Vacuum, IPA vapor, Drying Manifold” and U.S. patent application Ser. No. 10/404,270, filed on Mar. 31, 2003, entitled “Vertical Proximity Processor,” and U.S. patent application Ser. No. 10/404,692 filed on Mar. 31, 2003, entitled “Methods and Systems for Processing a Substrate Using a Dynamic Liquid Meniscus” and U.S. patent application Ser. No. 10,606,022, filed Jun. 24, 2003 and entitled “System and Method for Integrating In-Situ Metrology within a Wafer Process”. The aforementioned patent applications are hereby incorporated by reference in their entirety.

FIG. 4B illustrates a one embodiment of an exemplary substrate processing that may be conducted by a proximity head 450, in accordance with one embodiment of the present invention. Although FIG. 4B shows a top surface 458a of a substrate 200 being processed, it should be appreciated that the substrate process may be accomplished in substantially the same way for the bottom surface 458b of the substrate 200. While FIG. 4B illustrates a substrate drying process, many other fabrication processes may also be applied to the substrate surface in a similar manner. A source inlet 462 may be utilized to apply isopropyl alcohol (IPA) vapor toward a top surface 458a of the substrate 200, and a source inlet 466 may be utilized to apply deionized water (DIW) or other processing chemistry toward the top surface 458a of the substrate 200. In addition, a source outlet 464 may be utilized to apply vacuum to a region in close proximity to the wafer surface to remove fluid or vapor that may located on or near the top surface 458a. It should be appreciated that any suitable combination of source inlets and source outlets may be utilized as long as at least one combination exists where at least one of the source inlet 462 is adjacent to at least one of the source outlet 464 which is in turn adjacent to at least one of the source inlet 466. The IPA may be in any suitable form such as, for example, IPA vapor where IPA in vapor form is inputted through use of a N₂ carrier gas. Moreover, although DIW is utilized herein, any other suitable fluid may be utilized that may enable or enhance the wafer processing such as, for example, water purified in other ways, cleaning fluids, and other processing fluids and chemistries. In one embodiment, an IPA vapor inflow 460 is provided through the source inlet 462, a vacuum 472 may be applied through the source outlet 464 and DIW inflow 474 may be provided through the source inlet 466. Consequently, if a fluid film resides on the substrate 200, a first fluid pressure may be applied to the substrate surface by the IPA inflow 460, a second fluid pressure may be applied to the substrate surface by the DIW inflow 474, and a third fluid pressure may be applied by the vacuum 472 to remove the DIW, IPA vapor and the fluid film on the substrate surface.

Therefore, in one embodiment, as the DIW inflow 474 and the IPA vapor inflow 460 is applied toward a wafer surface, any fluid on the wafer surface is intermixed with the DIW inflow 474. At this time, the DIW inflow 474 that is applied toward the wafer surface encounters the IPA vapor inflow 460. The IPA forms an interface 478 (also known as an IPA/DIW interface 478) with the DIW inflow 474 and along with the vacuum 472 assists in the removal of the DIW inflow 474 along with any other fluid from the surface of the substrate 200. The IPA vapor/DIW interface 478 reduces the surface of tension of the DIW. In operation, the DIW is applied toward the substrate surface and almost immediately removed along with fluid on the substrate surface by the vacuum applied by the source outlet 464. The DIW that is applied toward the substrate surface and for a moment resides in the region between a proximity head and the substrate surface along with any fluid on the substrate surface forms a meniscus 476 where the borders of the meniscus 476 are the IPA/DIW interfaces 478. Therefore, the meniscus 476 is a constant flow of fluid being applied toward the surface and being removed at substantially the same time with any fluid on the substrate surface. The nearly immediate removal of the DIW from the substrate surface prevents the formation of fluid droplets on the region of the substrate surface being processed thereby reducing the possibility of contamination drying on the substrate 200. The pressure (which is caused by the flow rate of the IPA vapor) of the downward injection of IPA vapor also helps contain the meniscus 476.

The flow rate of the N₂ carrier gas for the IPA vapor assists in causing a shift or a push of water flow out of the region between the proximity head and the substrate surface and into the source outlets 304 through which the fluids may be output from the proximity head. Therefore, as the IPA vapor and the DIW is pulled into the source outlets 464, the boundary making up the IPA/DIW interface 478 is not a continuous boundary because gas (e.g., air) is being pulled into the source outlets 464 along with the fluids. In one embodiment, as the vacuum from the source outlet 464 pulls the DIW, IPA vapor, and the fluid on the substrate surface, the flow into the source outlet 464 is discontinuous. This flow discontinuity is analogous to fluid and gas being pulled up through a straw when a vacuum is exerted on combination of fluid and gas. Consequently, as the proximity head 450 moves, the meniscus 476 moves along with the proximity head, and the region previously occupied by the meniscus has been processed and dried due to the movement of the IPA vapor/DIW interface 478. It should also be understood that the any suitable number of source inlets 462, source outlets 464 and source inlets 466 may be utilized depending on the configuration of the apparatus and the meniscus size and shape desired. In another embodiment, the liquid flow rates and the vacuum flow rates are such that the total liquid flow into the vacuum outlet is continuous, so no gas flows into the vacuum outlet.

It should be appreciated any suitable flow rate may be utilized for the IPA vapor, DIW, and vacuum as long as the meniscus 476 can be maintained. In one embodiment, the flow rate of the DIW through a set of the source inlets 466 is between about 25 ml per minute to about 3,000 ml per minute. The flow rate of the DIW through the set of the source inlets 466 can be about 400 ml per minute. It should be understood that the flow rate of fluids may vary depending on the size of the proximity head. In one embodiment a larger head may have a greater rate of fluid flow than smaller proximity heads. This may occur because larger proximity heads, in one embodiment, have more source inlets 462 and 466 and source outlets 464 more flow for larger head.

The flow rate of the IPA vapor through a set of the source inlets 462 can be between about 1 standard cubic feet per hour (SCFH) to about 100 SCFH. The IPA flow rate is between about 5 and 50 SCFH. The flow rate for the vacuum through a set of the source outlets 464 is between about 10 standard cubic feet per hour (SCFH) to about 1250 SCFH. In a preferable embodiment, the flow rate for a vacuum though the set of the source outlets 464 is about 350 SCFH. In an exemplary embodiment, a flow meter may be utilized to measure the flow rate of the IPA vapor, DIW, and the vacuum.

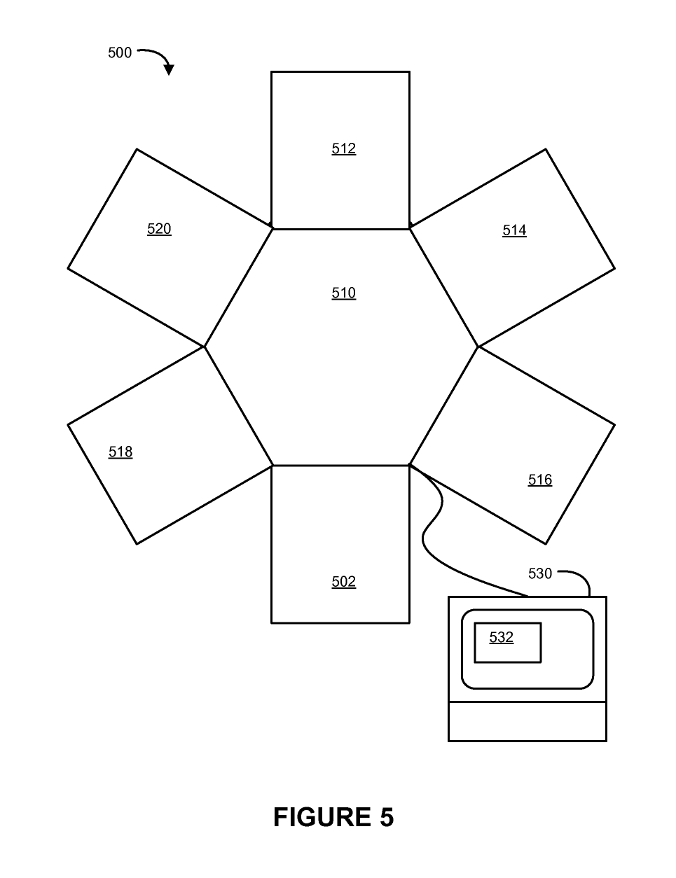

FIG. 5 is a simplified schematic diagram of a modular processing tool 500, in accordance with one embodiment of the present invention. The modular processing station 500 includes multiple processing modules 512-520, a common transfer chamber 510 and an input/output module 502. The multiple processing modules 512-520 can include one or more low pressure process chambers and atmospheric process chambers. The one or more low pressure process chambers have an operating pressure within a range of pressures of less than atmospheric pressure to a vacuum of less than about 10 mTorr. The low pressure process chamber can include more than one low pressure process chambers including a plasma chamber, a copper plating chamber including a mixer, a deposition chamber. The atmospheric pressure processing chamber can include one or more etch/removal chambers. The modular processing station 500 also includes a controller 530 that can control the operations in each of the multiple processing modules 512-520, the common transfer chamber 510 and the input/output module 502. The controller 530 can include one or more recipes 532 that include the various parameters for the operations in each of the multiple processing modules 512-520, the common transfer chamber 510 and the input/output module 502.

One or more of the multiple processing modules 512-520 can support etch operations, cleaning/rinsing/drying operations, plasma operations and the non-alkaline electroless copper plating operations. By way of example, chamber 518 can be a plasma chamber, chamber 520 can be a copper plating chamber (e.g., plating processing tool 400), chamber 512 can be an etch/removal chamber and chamber 514 can be a deposition chamber suitable for depositing barrier layers or BARC layers or catalytic layers as described above.

The common transfer chamber 510 can allow one or more substrates 200 to be transferred into and out of each of the processing modules 512-520 while remaining in the controlled environment (e.g., low oxygen and low water vapor levels) of the transfer chamber 510. By way of example the transfer chamber 510 can be maintained at a desired pressure (e.g., above or below atmospheric, vacuum), a desired temperature, a selected gas (e.g., argon, nitrogen, helium, etc. while maintaining an oxygen concentration of less than about 2 ppm).

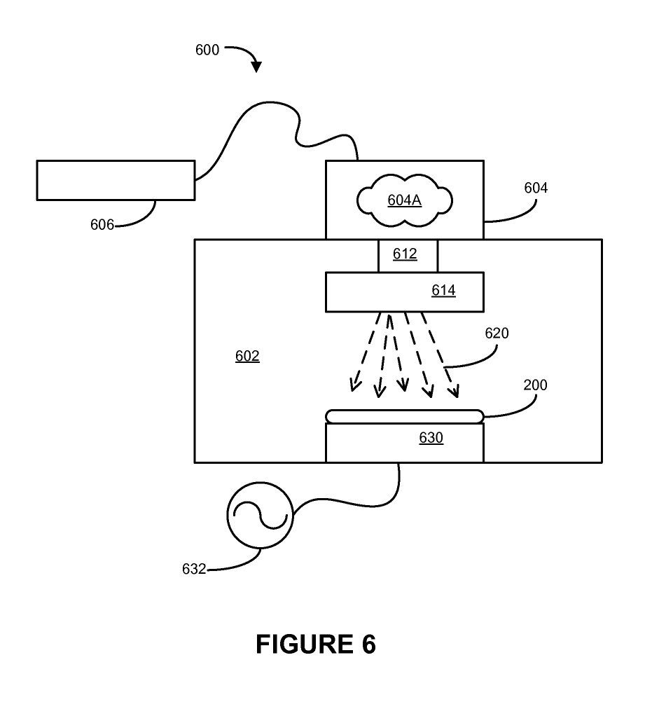

The plasma chamber 520 can be a conventional plasma chamber or a downstream plasma chamber. FIG. 6 is a simplified schematic diagram of an exemplary downstream plasma chamber 600, in accordance with one embodiment of the present invention. The downstream plasma chamber 600 includes a processing chamber 602. The processing chamber 602 includes a support 630 for supporting a substrate 200 being processed in the processing chamber 602. The processing chamber 602 also includes a plasma chamber 604 where a plasma 604A is generated. A gas source 606 coupled to the plasma chamber 604 and provides a gas used for generating the plasma 604A. The plasma 604A produces radicals 620 that are transported from the plasma chamber through a conduit 612 and into the processing chamber 602. The processing chamber 602 can also include a distributing device (e.g., showerhead) 614 that substantially evenly distributes the radicals 620 across the substrate 200. The downstream plasma chamber 600 generates the radicals 620 without exposing the substrate 200 to the relatively high electrical potentials and temperatures of the plasma 604A.

With the above embodiments in mind, it should be understood that the invention may employ various computer-implemented operations involving data stored in computer systems. These operations are those requiring physical manipulation of physical quantities. Usually, though not necessarily, these quantities take the form of electrical or magnetic signals capable of being stored, transferred, combined, compared, and otherwise manipulated. Further, the manipulations performed are often referred to in terms, such as producing, identifying, determining, or comparing.

Any of the operations described herein that form part of the invention are useful machine operations. The invention also relates to a device or an apparatus for performing these operations. The apparatus may be specially constructed for the required purposes, or it may be a general-purpose computer selectively activated or configured by a computer program stored in the computer. In particular, various general-purpose machines may be used with computer programs written in accordance with the teachings herein, or it may be more convenient to construct a more specialized apparatus to perform the required operations.

The invention can also be embodied as computer readable code on a computer readable medium. The computer readable medium is any data storage device that can store data which can thereafter be read by a computer system. Examples of the computer readable medium include hard drives, network attached storage (NAS), read-only memory, random-access memory, CD-ROMs, CD-R5, CD-RWs, magnetic tapes, and other optical and non-optical data storage devices. The computer readable medium can also be distributed over a network coupled computer systems so that the computer readable code is stored and executed in a distributed fashion.

It will be further appreciated that the instructions represented by the operations in the above figures are not required to be performed in the order illustrated, and that all the processing represented by the operations may not be necessary to practice the invention. Further, the processes described in any of the above figures can also be implemented in software stored in any one of or combinations of the RAM, the ROM, or the hard disk drive.

Although the foregoing invention has been described in some detail for purposes of clarity of understanding, it will be apparent that certain changes and modifications may be practiced within the scope of the appended claims. Accordingly, the present embodiments are to be considered as illustrative and not restrictive, and the invention is not to be limited to the details given herein, but may be modified within the scope and equivalents of the appended claims.

What is claimed is:

1. A method for forming copper on a substrate comprising:
forming a tantalum layer on the substrate;
forming a ruthenium seed layer on the tantalum layer;
forming a photoresist layer on the ruthenium seed layer;
removing an undesired portion of the photoresist layer leaving only desired portion of the photo resist layer, wherein removing the undesired portions of the photoresist layer exposes a first portion of the ruthenium seed layer;
producing a plating solution including copper ions suspended in a substantially neutral or acidic solution that does not react with the desired portion of the photo resist layer, wherein the desired portion of the photo resist layer does not include a protective layer;
applying the plating solution to the first portion of the ruthenium seed layer;
reducing a copper oxide in the plating solution to elemental copper using a cobalt ion solution instead of an aldehyde;
forming copper on the first portion of the ruthenium seed layer at a rate greater than about 500 Angstrom per minute up to about 2500 Angstrom per minute;
removing the desired portion of the photo resist layer to expose a second portion of the ruthenium seed layer;
removing the second portion of the ruthenium seed layer in a plasma etch process to expose a first portion of the tantalum layer; and
removing the first portion of the tantalum layer in the plasma etch process.

2. The method of claim 1, wherein the tantalum layer has a thickness of between a mono layer and about 500 Angstroms.

3. The method of claim 1, wherein the tantalum layer has a thickness of less than about 360 Angstroms.

4. The method of claim 1, wherein the tantalum in the tantalum layer includes tantalum nitride.

5. The method of claim 1, wherein the ruthenium seed layer has a thickness of between a mono layer and about 500 Angstroms.

6. The method of claim 1, wherein the ruthenium seed layer has a thickness of less than about 150 Angstroms.

7. The method of claim 1, wherein the plating solution has a temperature of between about 20 degrees C. and less than 70 degrees C.

8. The method of claim 1, wherein the plating solution has pH of between about 7.2 and about 7.8.

9. The method of claim 1, wherein the plating solution has pH of greater than about 6.8.

10. The method of claim 1, wherein undesired portion of the photoresist layer includes removing oxides on the first portion of the ruthenium seed layer.

11. A method for forming copper on a substrate comprising:
forming a tantalum layer on the substrate;
forming a ruthenium seed layer on the tantalum layer, wherein the ruthenium seed layer has a thickness of between a mono layer and about 500 Angstroms;
forming a photoresist layer on the ruthenium seed layer;
removing an undesired portion of the photoresist layer leaving only desired portion of the photo resist layer, wherein removing the undesired portions of the photoresist layer exposes a first portion of the ruthenium seed layer;
producing a plating solution including copper ions suspended in a substantially neutral or acidic solution that does not react with the desired portion of the photo resist layer, wherein the desired portion of the photo resist layer does not include a protective layer;
applying the plating solution to the first portion of the ruthenium seed layer, wherein the plating solution has a temperature of between about 20 degrees C. and less than 70 degrees C.;
reducing a copper oxide in the plating solution to elemental copper using a cobalt ion solution instead of an aldehyde;
forming copper on the first portion of the ruthenium seed layer at a rate greater than about 500 Angstrom per minute up to about 2500 Angstrom per minute;
removing the desired portion of the photo resist layer to expose a second portion of the ruthenium seed layer;
removing the second portion of the ruthenium seed layer in a plasma etch process to expose a first portion of the tantalum layer; and
removing the first portion of the tantalum layer in the plasma etch process.

12. A method for forming copper on a substrate comprising:
forming a tantalum nitride layer on the substrate;
forming a ruthenium seed layer on the tantalum nitride layer, wherein the ruthenium seed layer has a thickness of between a mono layer and about 500 Angstroms;
forming a photoresist layer on the ruthenium seed layer;
removing an undesired portion of the photoresist layer leaving only desired portion of the photo resist layer, wherein removing the undesired portions of the photoresist layer exposes a first portion of the ruthenium seed layer;
producing a plating solution including copper ions suspended in a substantially neutral or acidic solution that does not react with the desired portion of the photo resist layer, wherein the desired portion of the photo resist layer does not include a protective layer;
applying the plating solution to the first portion of the ruthenium seed layer, wherein the plating solution has a temperature of between about 20 degrees C. and less than 70 degrees C.;
reducing a copper oxide in the plating solution to elemental copper using a cobalt ion solution instead of an aldehyde;
forming copper on the first portion of the ruthenium seed layer at a rate greater than about 500 Angstrom per minute up to about 2500 Angstrom per minute;
removing the desired portion of the photo resist layer to expose a second portion of the ruthenium seed layer;
removing the second portion of the ruthenium seed layer in a plasma etch process to expose a first portion of the tantalum nitride layer; and
removing the first portion of the tantalum nitride layer in the plasma etch process.
